(19) United States
(12) Patent Application Publication
(10) Pub. No.: US 2013/0161514 A1
(43) Pub. Date: Jun. 27, 2013

(54) HIGH-SPEED GIGA-TERAHERTZ IMAGING DEVICE AND METHOD

(71) Applicants: Igor Kukushkin, Chernogolovka (RU); Viacheslav Muravev, Noginsk (RU); Gombo Tsydynzhapov, Chernogolovka (RU); Anton Fortunatov, Himki (RU)

(72) Inventors: Igor Kukushkin, Chernogolovka (RU); Viacheslav Muravev, Noginsk (RU); Gombo Tsydynzhapov, Chernogolovka (RU); Anton Fortunatov, Himki (RU)

(21) Appl. No.: 13/336,912

(22) Filed: Dec. 23, 2011

(51) Int. Cl. H01L 27/146

(52) U.S. Cl. 250/332

(57) ABSTRACT

A high-speed room-temperature imaging system, especially for electromagnetic radiation in the GHz and THz frequency range, is based on the sensor consisting of a matrix of plasmonic semiconductor detectors. The imaging system comprises a radiation source module, a terahertz beam director module, a plasmonic imaging sensor module, and a signal processing module. Entire image is formed simultaneously providing for high-speed image acquisition. Images can be acquired either at a single frequency (discrete spectrum) or wide frequency bands (continuous spectrum). The imaging system can be used in defectoscopy, inspection, medical and other applications.

### BACKGROUND

The present invention relates to apparatus and method for obtaining digital images in gigahertz (GHz)-terahertz (THz) frequency range. The terahertz range (T-rays) refers to electromagnetic waves with frequencies between 100 GHz and 10 THz. Located between radio waves and infrared light, it has a number of unique properties. THz radiation can penetrate non-metallic non-polar materials, e.g. organic substances, skin, fabrics, plastics, paper products. Because of low energy of photons, the radiation does not cause ionization and does not produce any damage that can be caused by X-rays or gamma-radiation. It is not harmful to tissues and DNA. THz radiation can be used instead of X-rays for non-destructive examination of various types of articles, such as envelopes, boxes, cases etc. Moreover, while X-ray tomography systems are capable of analyzing only density and shape of the article, THz imaging systems can differentiate materials based on the fact that many substances have distinct spectral and refractive features in the THz frequency range. Because of these properties, terahertz radiation is widely used in many commercial applications, e.g., manufacturing, food control, non-destructive testing, security analytics, medical imaging, and art authenticity control. Existing terahertz imaging systems possess an obvious disadvantage—they are of scanning type and their sampling rates are very low. It usually takes minutes to capture one image of an object because an image is obtained pixel by pixel through mechanical scanning by a single detector. That makes T-rays imaging instruments bulky, difficult to use, and prohibitively expensive.

### SUMMARY

The following is a summary description of illustrative embodiments of the present invention. It is provided as a preface to assist those skilled in the art to more rapidly assimilate the detailed design discussion which ensues and is not intended in any way to limit the scope of the claims, which are appended hereto in order to particularly point out the invention.

The present invention builds upon the technology and invention described and claimed in U.S. patent application Ser. No. 12/247,096, which is incorporated herein by reference. The embodiments disclosed hereafter utilize the present invention, which provides a new miniature gigahertz-terahertz imaging system based on the sensor consisting of a matrix of plasmonic semiconductor detector that features high sampling rate at the room temperature. The imaging sensor can be manufactured on a single wafer in a unified lithographic process. That ensures high homogeneity and reproducibility of the detector parameters. Depending on the parameters of the plasmonic detector (some embodiments of which are described in detail in U.S. patent application Ser. No. 12/247,096) the frequency band of the imaging system of the preferred embodiment covers frequency range from approximately 1 GHz to approximately 10 THz. The plasmonic detector may include one or more antenna structures that provide narrow-band selectivity and increased responsivity. The plasmonic detector can also be realized without antenna structures, yielding wide-band response.

The first aspect of the invention provides a room-temperature imaging system. The system can comprise one or more semiconductor structures, each consisting of at least one matrix of plasmonic detectors. Each matrix can be tuned to a specific frequency or a frequency band. Said imaging sensor can be fabricated using any now known or later developed semiconductor material that is suitable to produce at least one two-dimensional charge layer. For example, AlGaAs/GaAs heterostructures or Si FET-structures can be employed.

Optionally, the imaging system may include apparatus or an array of apparatuses that generate GHz-THz radiation. The apparatuses can be manufactured using any process now known or later developed, in particular, IMPATT diode or Gunn oscillator concepts. Each apparatus may generate at a specific frequency or over a frequency range. Additionally, said imaging system may include amplification, analog-digital converter, and reading electronic circuits. They are intended to amplify and record signals originating from the matrix of plasmonic detectors and direct them to a computer bus. Then, computer software can be used to interpret and analyze the obtained set of information, and to present images in a convenient way.

The second aspect of the invention provides a method of imaging a sample, the method comprising the following steps:

1. Generating electromagnetic radiation by a single oscillator/array of oscillators at a single frequency or plurality of frequencies.

2. Directing the radiation onto the object under investigation.

3. Collecting the reflected/transmitted electromagnetic radiation onto the imaging sensor, and detecting radiation from each matrix detector.

4. Producing an image from the radiation detected in step (3) using a frequency or a selection of frequencies from the plurality of frequencies in the incident broad-band electromagnetic radiation.

In the third aspect, possible applications of the present invention are claimed. The first set of applications is related to security. Main advantages of the invention in this area is its ability to see through many common packaging materials and clothing in combination with high-speed operation and small size. Because of the high-speed, the terahertz imaging system can be used to develop high-throughput screening system for automatic or semi-automatic examination of letters, parcels, and other postal items for security threats of various nature. Because the system is light and compact, it can be turned into a hand-held device to be used by security personnel in various scenarios to detect concealed firearms, knives, and other weapons. It also can be used to create full-body imaging system for airport security and the like.

The second kind of applications is non-destructive testing. Terahertz imaging can be employed to control integrity of surfaces covered with layers of paint, varnishes, or sediments such as car bodies or oil and gas pipes. Because of the compact equipment size, it can be used in places that are difficult to access.

The third kind of application is related to biomedical imaging. Terahertz rays can penetrate several millimeters under skin, and it can be used to detect surface diseases, for example, skin cancer. Also, certain organic molecules have characteristic absorption lines in the terahertz range. Imaging performed using radiation source tuned to that frequency can be used to detect presence of said molecules in biological samples, including live tissues.

Operation of the imaging apparatus has been demonstrated for a sensor made on the basis of a single quantum well GaAs/AlGaAs wafer. The sensor consisted of 32×32 detectors and it was interrogated at 100 Hz rate. Successful operation of the imaging device has been verified for the frequency range from 20 GHz to 0.7 THz. Embodiments operating at higher sampling rates can be implemented according to the principles set forth herein.

### DESCRIPTION OF DRAWINGS

FIG. 1 shows frequency dependence of responsivity measured for a plasmonic detector;

FIG. 2 shows responsivity of 15 plasmonic detectors arbitrarily chosen from the imaging sensor array;

FIG. 3 shows spectra of the heterodyne signal from a plasmonic detector for three intermediate frequencies Δf =10.35, 29.83, and 40.82 GHz. The frequency of the heterodyne source was f₀=60.35 GHz. The signal from the plasmonic detector decreases by a factor of only one fourth when the intermediate frequency increases up to 40 GHz (inset). Therefore, the response bandwidth of the detector is at least 40 GHz, correspondingly, the response time of the detector is no more than τ=25 ps.

FIG. 4 shows schematic diagram of GHz-THz imaging system operating in the reflection mode;

FIG. 5 shows schematic diagram of GHz-THz imaging system operating in the transmission mode;

FIG. 6 shows schematic diagram of GHz-THz imaging system operating in the passive mode;

FIG. 7 shows an optical image of a metallic cross in a plastic box with the box open (FIG. 7a) and the box closed (FIG. 7b);

FIG. 8 shows the THz image (0.2 THz) of the metallic cross hidden in the closed box captured in the transmission mode. The image acquisition time was 0.5 s;

FIG. 9 shows an optical image of a metal nut in a plastic box with the box open (FIG. 9a) and the box closed (FIG. 9b);

FIG. 10 shows the THz image (0.2 THz) of the nut hidden in the closed box captured in the transmission mode. The image acquisition time was 0.5 s;

FIG. 11 shows an optical image of a metallic ring in a plastic box with the box open.

FIG. 12 shows an optical image of a metallic ring in a plastic box with the box closed. Superimposed is a THz image obtained at 0.2 THz (color diagram), the image being of the closed box and captured in the reflection mode. The distance between the box and the imaging device equals to 0.5 m. The image acquisition time is 0.5 s.

FIG. 13 shows THz images captured by the imaging apparatus of a focused beam for two frequencies 203 GHz and 371 GHz;

### DETAILED DESCRIPTION

Operation of an illustrative device was demonstrated for the imaging sensor that comprised 32×32 detectors. The device consisted of a set of sensor chips backed by op-amp amplifiers and ADC data acquisition unit. The amplifiers were assembled from standard components. An off-the-shelf device was used for ADC.

The sensor chips may be fabricated from a AlGaAs/GaAs heterostructure wafer 0.5 mil thick that comprises a single-well, two-dimensional electron system with a density of n_{S}=6×10¹¹ cm⁻² and mobility of μ=10000 cm²/Vs (at room temperature). Details of the lithographic process are described in detail in U.S. patent Application Ser. No. 12/247,096.

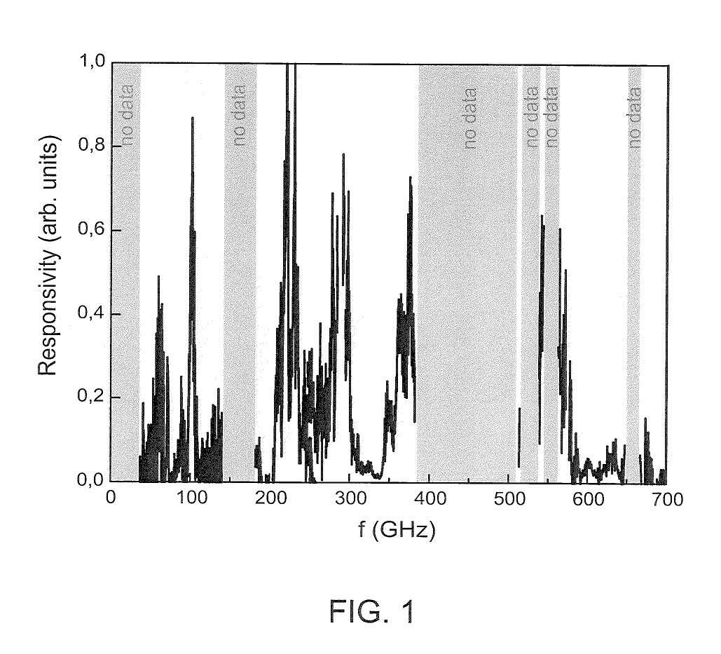

Each AlGaAs/GaAs chip carries sixteen 1 mm×1 mm plasmonic detectors with common ground. A reflector is formed on the reverse side of the chips by a layer of gold. Characteristic responsivity curve for the detectors measured over the available span of radiation sources is shown in FIG. 1. The estimated maximum detector responsivity equals to 100 V/W with noise equivalent power (NEP) being 2 pW/Hz^{0.5}. Peaks and troughs of the responsivity curve are determined by the substrate modes and can be changed as necessary by the varying thickness of the wafer. The detectors proper are extremely wide-band in this case (estimated band-width is about 1 THz). However, it is possible to incorporate antennas into each detector in order to gain highly-selective narrow-band responsivity curve. In this case, frequency response is determined exclusively by properties of the antennas.

One embodiment uses a relatively low-performing setup that consists of op-amp integrating amplifiers (one amplifier multiplexed per 32 detectors) and external ADC unit. Image acquisition rate 10 fps can be achieved. Making a dedicated chip with an amplifier for each detector and a fast ADC, possibly integrated on the same chip, would dramatically increase performance.

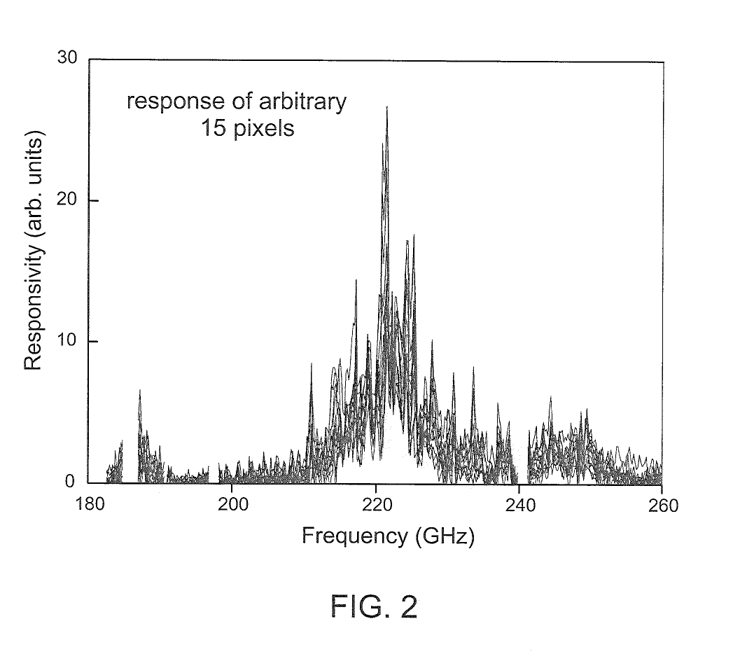

The imaging sensor of the preferred embodiment can be manufactured by a unified lithographic process on a single wafer. That process ensures high homogeneity and reproducibility of the plasmonic detector parameters. FIG. 2 shows the responsivity of 15 random plasmonic detectors from the imaging sensor array. The responsivity curves reflect identical frequency dependences with peak deviation within an approximately 20-percent range. Such high homogeneity of detectors makes it possible to obtain a detailed image of objects in GHz-THz frequencies without “black” pixels.

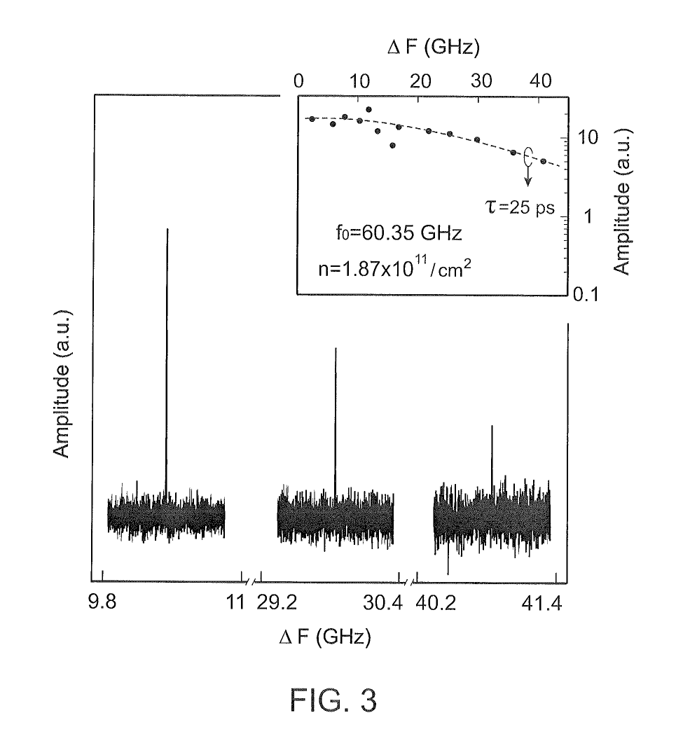

The time response of the plasmonic detector can be measured by the heterodyne technique at 77 K. Electromagnetic radiation from the signal and heterodyne generators is mixed and directed onto a single plasmonic detector. Radiation at the intermediate frequency that originates from the detector passes via a stripline and coaxial cable to the input of a spectrum analyzer. FIG. 3 shows spectra of the signal from a non-linear plasmonic detector for three intermediate frequencies Δf=10.35, 29.83, and 40.82 GHz. The frequency of the heterodyne source is f₀=60.35 GHz, its output power is 10 mW, and the output power of the signal generator is 1 mW. It can be seen that the amplitude of the signal from the plasmonic detector decreases by a factor of only one fourth when the intermediate frequency increases up to 40 GHz (the instrumental limit for the spectrum analyzer). Therefore the response bandwidth of the detector is at least 40 GHz (inset to FIG. 3); correspondingly, the response time of the non-linear detector is no more than τ=25 ps. Such short response time of a single plasmonic detector potentially allows for extremely high sampling rate of an imaging system assembled from the detectors of this kind. The explanation for such high rates of the plasmonic device response is presumably as follows. Operation of all conventional electronic millimeter/submillimeter receivers relies on the non-linearity in the drift of charge carriers. Because of that, the response time of τ is limited by the time L/v even in the ballistic regime, where L is the size of the non-linear element of the detector (L is usually about 1 micrometer or more) and v is the typical velocity of charge carriers in the device (usually, v is about the Fermi velocity and is no more than 10⁷ cm/s). Therefore, the response time of the device is fundamentally limited by the time τ□10 ⁻¹¹ s and the response bandwidth by a frequency of 100 GHz. One of the possibilities of decreasing the response time of modern electronic devices, realized in the present invention, is the use of plasma waves as carriers of electric signals. Indeed, the velocity of plasma excitations in two-dimensional electron systems can reach vₚ=10⁹cm/s, which is two orders of magnitude higher than the maximally attainable electron drift velocity. This can reduce the response time of devices to τ□10⁻¹³ s and increase the response bandwidth to a frequency of 10 THz (L=1 micron). For the plasmonic detectors in question the system response time of τ=25 ps at a device size of L=0.2 mm indicates that plasma perturbation propagates in the system at velocity of no less than vₚ=0.8z×10⁹ cm/s. This value is consistent with theoretical estimates.

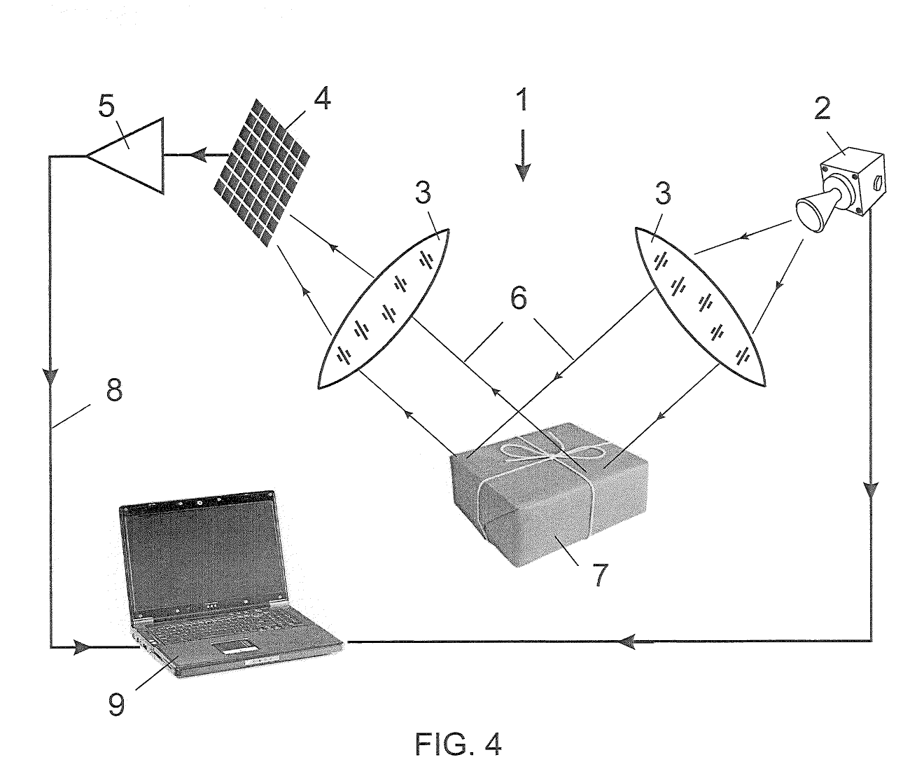

FIG. 4 shows a schematic diagram of imaging apparatus 1 operating in the reflection mode. System 1 includes radiation source module 2, terahertz beam director module 3, plasmonic imaging sensor module 4, and signal processing module 5. GHz-THz radiation is generated by the radiation source module 2 by using any type of emitter. The emitter can be realized in a number of ways, for example, by using IMPATT, TUNNET, or Gunn diodes, and backward wave oscillators. Electromagnetic radiation beam 6 from radiation source module 2 is directed onto object under investigation 7 via beam director module 3. Beam director module 3 may include any type of GHz-THz optics or guiding instruments now known or later developed. For instance, module 3 may include lenses, mirrors, prisms, beam splitters, phase shifters, polarizers, band pass filters, etc. The reflected radiation, which contains information about the internal structure of object 7 is then directed via further optics into imaging sensor module 4. Imaging sensor 4 includes an array of plasmonic detectors. An illustrative embodiment of the imaging sensor is disclosed in detail hereabove.

The plurality of electrical signals from imaging sensor module 4 is routed to signal processing module 5. The function of signal processing module 5 is to transform the analogue signals from the imaging sensor into a digital computer-compatible format. Processing module 5 may include any sort of electronic circuitry now existing or later developed. In particular, module 5 may include amplifiers, analog-to-digital converters, multiplexers, switches, microcontrollers, memory and storage devices, etc. Processing module 5 may be represented in the form of a circuit assembled of discrete elements, or in the form of integrated chip, or in any combination of those. The data from signal processing module 5 may be delivered to computer 9 in real time or otherwise.

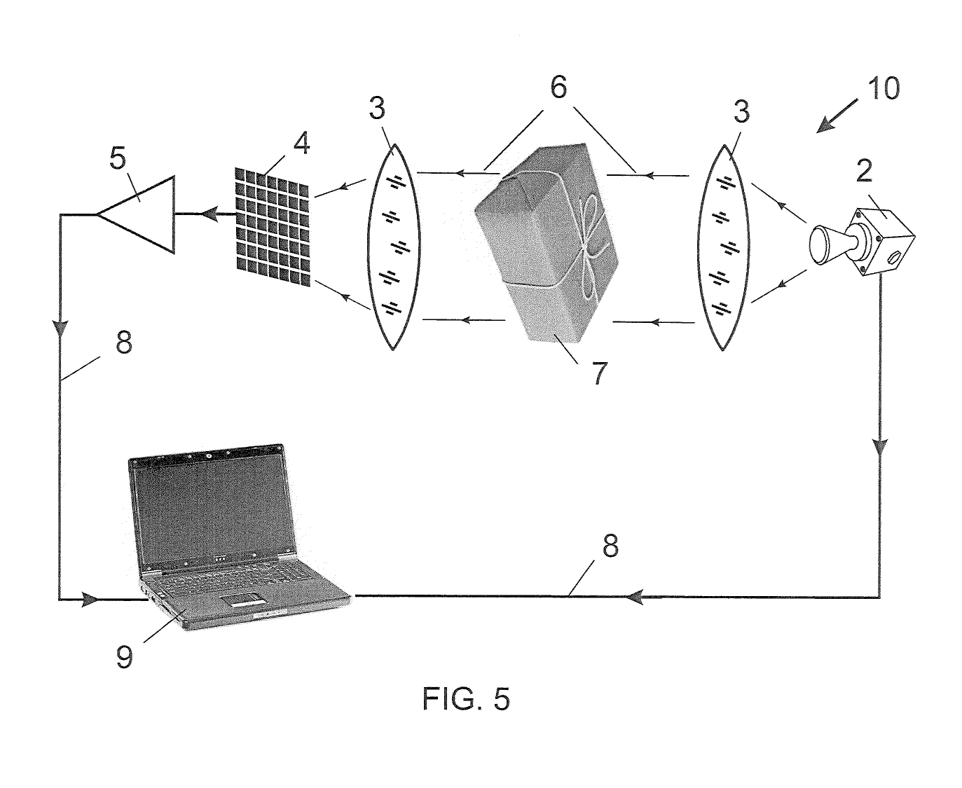

FIG. 5 shows an alternative schematic imaging apparatus 10 according to another embodiment of the invention. Imaging system 10 operates in the transmission mode. In this embodiment, GHz-THz radiation 6 from radiation source module 2 penetrates through object 7 under examination. In many cases such configuration is preferable due to a better signal-to-noise-ratio. In addition, transmission measurements provide complementary information to reflection measurements to reconstruct a 3D-tomographic image of the object.

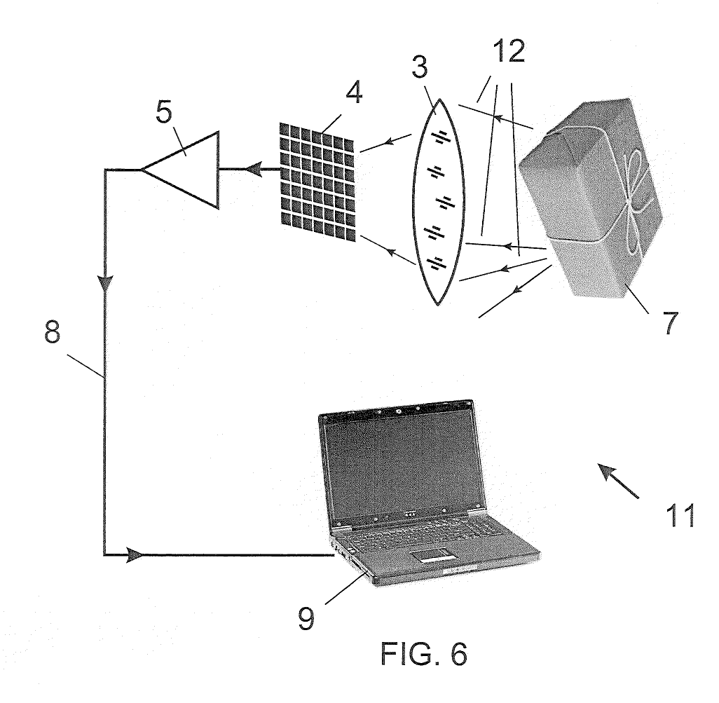

In the device embodiments 1 and 10, as shown in FIGS. 4 and 5, GHz-THz image is obtained at a plurality of frequencies defined by radiation source module 2. In these embodiments, background thermal electromagnetic radiation from object 7 is ignored and/or subtracted from the final image. At the same time, in the device embodiment 11 (FIG. 6), radiation employed by the imaging system is thermal radiation 12 from object 7. Referring to FIGS. 4 through 6, it is understood that actual imaging system may include any combination of aforementioned reflection/transmission/passive modes.

Additionally, imaging systems 1 and 10 in FIGS. 4 and 5 may include a moving support for exposing multiple objects to said imaging system. Such moving support may be implemented as a conveyor to increase the speed and throughput capacity of the imaging system. Although not shown, embodiments of the device in accordance with the present invention may comprise modulators (e.g, choppers) and other implements intended to reduce the offset drift and to increase the signal-to-noise-ratio.

Of considerable interest for many applications is the ability of the imaging system to inspect the chemical composition of object 7 in a non-destructive manner. Thus, a technique that combines imaging and spectroscopic capabilities to locate and identify substances may present significant advantages.

Spectroscopic response may be obtained in the following ways: (A) radiation source module 2 may include sub-arrays of emitters, each having a specific frequency, and imaging module 4 may include sub-arrays of plasmonic detectors, each tuned to a specific frequency consistent with the frequencies of the emitters; (B) radiation source module 2 may include sub-arrays of emitters each having specific frequency and operating sequentially, imaging module 4 may include unified set of wide-band plasmonic detectors and selectivity in frequency is achieved by synchronizing data acquisition with operation times of specific emitter sub-arrays; or (C) radiation source module 2 may include a continuous spectrum (for example, white noise) emitter, and imaging module 4 may include sub-arrays of plasmonic detectors, each tuned to a specific frequency. In all cases, the polychromatic electromagnetic radiation is reflected/transmitted from object 7 and guided to imaging sensor module 4. By using this technique, a discrete spectrum of different parts of the object can be captured.

The main advantages of an apparatus according to the present invention is its ability to see through many common packaging materials and clothings in combination with a high-speed operation and small size. Terahertz radiation is able to penetrate through lots of common materials, such as packaging materials, woods, and building materials.

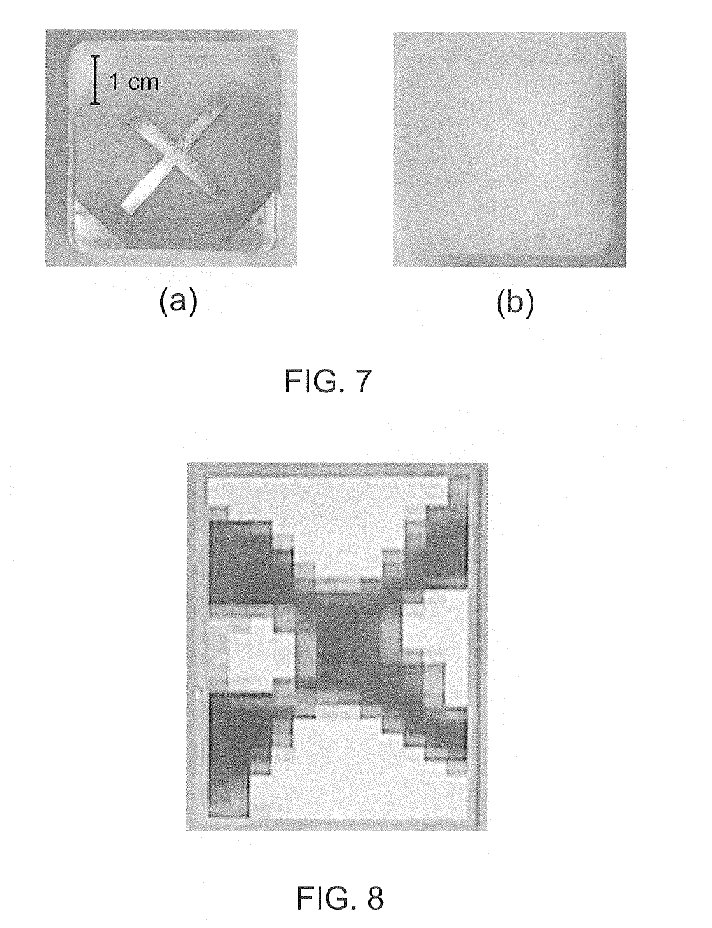

FIG. 7a shows a visible image of a metallic cross placed in a plastic box. At visible wavelength it was not possible to observe the contents of the plastic box with the lid closed, FIG. 7b. The metallic cross in the closed box was imaged at 200 GHz using imaging apparatus 10 in a transmission mode. Imaging sensor 4 includes 32×32 plasmonic detectors with 1 mm pinch. Analyzing THz field distribution captured by sensor 4 with and without the closed box, a THz image was formed on the contents of the box, FIG. 8. The light areas correspond to regions of highest THz transmission. The metallic cross is clearly visible inside the closed box. Image acquisition time was 0.5 s.

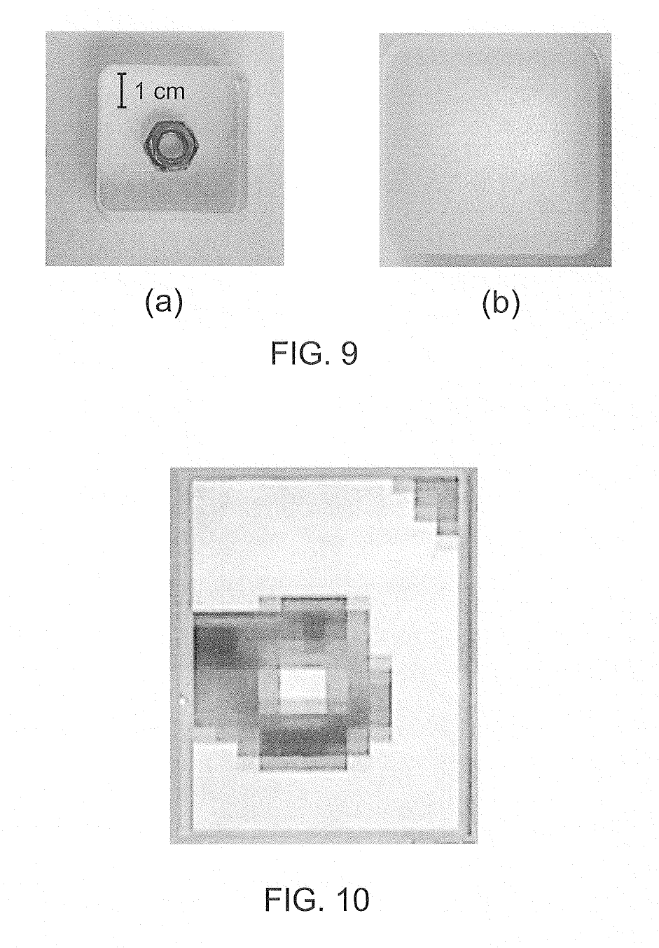

FIGS. 9-10 depict similar experiments performed with a metal nut placed in a plastic box. FIG. 9a shows a visible image of the metal nut, while FIG. 9b depicts the closed plastic box. FIG. 10 shows an image of the closed plastic box with the nut inside at 200 GHz.

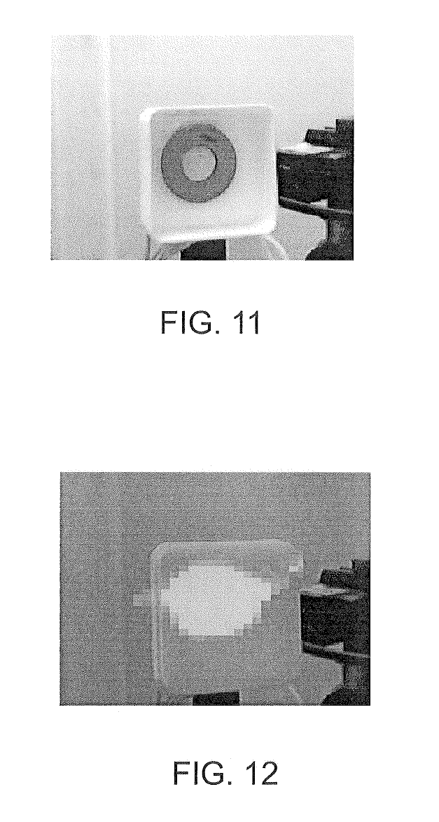

FIGS. 11 and 12 show imaging experiments performed in the reflection mode. FIG. 11 shows an optical image of a metallic ring in a plastic box with the box open.

FIG. 12 shows an optical image of a metallic ring in a plastic box with the box closed. Superimposed is THz image obtained at 0.2 THz. The image is of the closed box and it is captured in the reflection mode. The light areas correspond to regions of the maximum THz reflection. The distance between the box and the imaging device equals to 0.5 m. The image acquisition time was 0.5 s. These examples demonstrate the feasibility of applications in the areas of high-speed nondestructive evaluation and security inspections.

Spatial resolution of the imaging apparatus in the far-field operation (when the distance from object 7 to imaging module 4 is much greater than the wavelength) is determined by the frequency of the electromagnetic radiation.

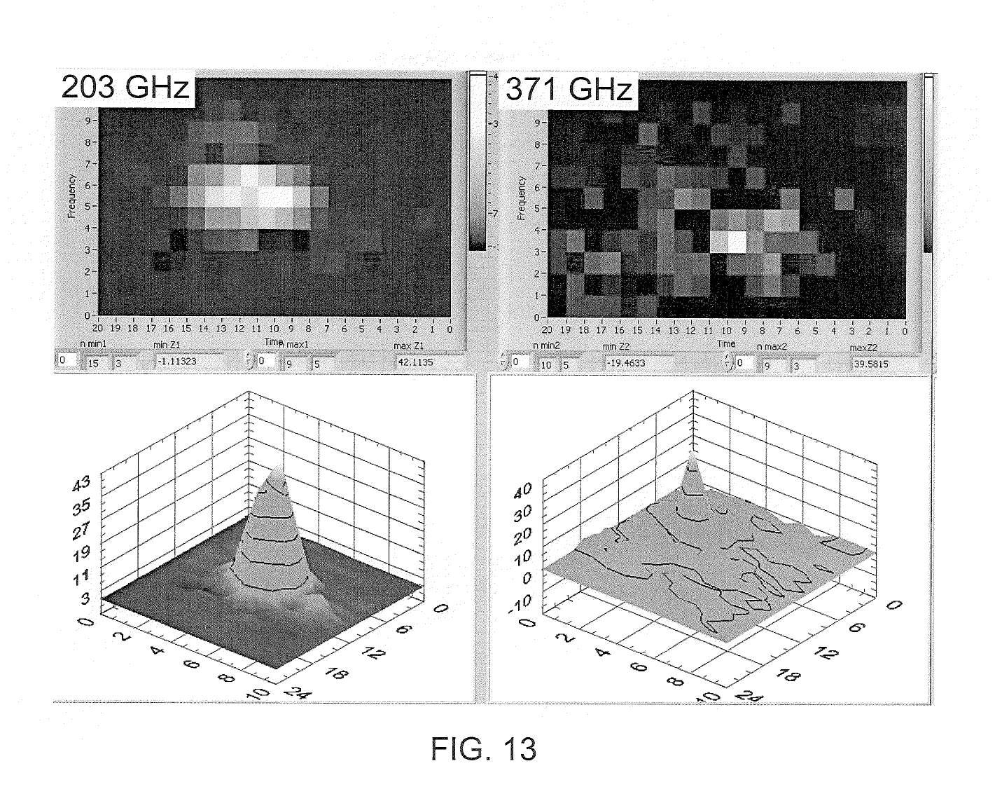

FIG. 13 shows THz images of a focused beam for two frequencies: 203 GHz and 371 GHz. In the upper portion of FIG. 13, the light areas correspond to the regions of highest beam power captured by the imaging sensor. The bottom portion of FIG. 13 shows a beam power distribution over the area of the imaging sensor. The focus spot size is inversely proportional to the radiation frequency. Therefore, finer details can be resolved by the imaging sensor at higher frequencies.

The foregoing description of various embodiments of the invention has been presented for purposes of illustration and description. Many modifications and variations are possible. Such modifications and variations that may be apparent to a person skilled in the art are intended to be included within the scope of the appended claims.

What we claim is:

1. An imaging device comprising one or more plasmonic detectors.

2. The imaging device of claim 1 further comprising a processing module including an amplifier, an analog to digital converter, a multiplexer and a switch.

3. The imaging device of claim 1 further comprising a source of electromagnetic radiation.

4. The imaging device of claim 1 further comprising a beam director module including a lens.

5. The imaging device of claim 1 further comprising a beam director module including a mirror.

6. The imaging device of claim 1 further comprising modulator.

7. The imaging device of claim 2 further comprising a processor.

8. A method for capturing an image, the method comprising:
generating electromagnetic radiation;
directing said electromagnetic radiation at an object which said electromagnetic radiation penetrates, thereby causing penetrated electromagnetic radiation; and
registering said penetrated electromagnetic radiation with an imaging device comprising one or more plasmonic detectors.

9. A method for capturing an image comprising:
generating electromagnetic radiation;
directing said electromagnetic radiation at an object from which said electromagnetic radiation reflects, thereby causing reflected electromagnetic radiation; and
registering said reflected electromagnetic radiation with an imaging device comprising one or more plasmonic detectors.

10. A method for capturing an image of an object comprising registering background thermal electromagnetic radiation of said object by an imaging device comprising one or more plasmonic detectors.
